(19) United States
(12) Patent Application Publication
(10) Pub. No.: US 2015/0124549 A1
(43) Pub. Date: May 7, 2015

(54) SEMICONDUCTOR DEVICES

(71) Applicant: SK hynix Inc., Icheon-si Gyeonggi-do (KR)

(72) Inventor: Kyu Young KIM, Guri-si Gyeonggi-do (KR)

(73) Assignee: SK hynix Inc., Icheon-si Gyeonggi-do (KR)

(21) Appl. No.: 14/244,733

(22) Filed: Apr. 3, 2014

(30) Foreign Application Priority Data
Nov. 6, 2013 (KR) 10-2013-0134315

(51) Int. Cl. H03K 5/153; G11C 8/18

(52) U.S. Cl. CPC H03K 5/153; G11C 8/18
USPC 365/233.1; 327/172; 327/176

(57) ABSTRACT

The semiconductor device includes a pulse width comparator suitable for generating an internal pulse signal having the same pulse width as an output pulse signal whose pulse width is controlled by first and second control signals during a predetermined period and suitable for generating first and second digital signals and a comparison pulse signal from the internal pulse signal according to a delay time which is set by the first and second control signals, an output pulse signal generator suitable for retarding the comparison pulse signal by the delay time determined by first and second control signals to generate the output pulse signal, and a control signal generator suitable for generating the first and second control signals which are sequentially enabled in response to pulses of the output pulse signal.

### CROSS-REFERENCE TO RELATED APPLICATION

The present application claims priority under 35 U.S.C 119(a) to Korean Application No. 10-2013-0134315, filed on Nov. 6, 2013, in the Korean Intellectual Property Office, which is incorporated herein by reference in its entirety as set forth in full.

### TECHNICAL FIELD

Embodiments relate to semiconductor devices.

### BACKGROUND

As semiconductor devices are becoming highly integrated and operate at relatively faster speeds, frequencies of external clock signals applied to the semiconductor devices have increased. Delay locked loop (DLL) circuits or phase locked loop circuits have been widely used in semiconductor devices to improve the adaptability of the semiconductor devices to relatively higher frequency external clock signals.

Semiconductor devices may often include a time-to-digital converter (TDC) that measures a time interval between an input signal and a reference signal. The TDC may receive two signals of the input signal and the reference signal to measure a pulse width and a delay time of the input signal.

In many instances, semiconductor devices may generate a digital signal corresponding to the input signal using a successive approximate register (SAR). The digital signal corresponding to the input signal may be obtained by comparing the input signal with the reference signal and by sequentially generating bit levels of the digital signal beginning with a most significant bit (MSB) according to the comparison result.

### SUMMARY

An embodiment of a semiconductor device includes a pulse width comparator, an output pulse signal generator and a control signal generator. The pulse width comparator generates an internal pulse signal including a pulse having substantially the same pulse width as a pulse of an output pulse signal, wherein the pulse width of the output pulse signal is based on first and second control signals during a period corresponding to a pulse width of an input pulse signal. The pulse width comparator generates first and second digital signals and a comparison pulse signal based on the internal pulse signal in accordance with a delay time based on the first and second control signals. The output pulse signal generator delays the comparison pulse signal by the delay time based on the first and second control signals to generate the output pulse signal. The control signal generator generates the first and second control signals, wherein the first and second control signals are sequentially enabled in response to pulses of the output pulse signal.

An embodiment of a semiconductor device includes a first logic unit, a comparator and an output pulse signal generator. The first logic unit generates an internal pulse signal including a pulse having substantially the same width as a pulse of an output pulse signal during a period corresponding to a pulse width of an input pulse signal. The comparator delays the internal pulse signal by a delay time based on a logic level combination of first and second control signals to generate a delay pulse signal. The comparator outputs the internal pulse signal as first and second digital signals in synchronization with pulses of the delay pulse signal. The comparator generates a comparison pulse signal in response to the first and second digital signals. The output pulse signal generator delays the comparison pulse signal by the delay time based on the first and second control signals to generate the output pulse signal.

An embodiment of a system includes a memory controller and a semiconductor memory device. The semiconductor memory device includes a pulse width comparator, an output pulse signal generator and a control signal generator. The pulse width comparator generates an internal pulse signal including a pulse having substantially the same pulse width as a pulse of an output pulse signal, wherein the pulse width of the output pulse signal is based on first and second control signals during a period corresponding to a pulse width of an input pulse signal. The pulse width comparator generates first and second digital signals and a comparison pulse signal based on the internal pulse signal in accordance with a delay time based on the first and second control signals. The output pulse signal generator delays the comparison pulse signal by the delay time based on the first and second control signals to generate the output pulse signal. The control signal generator generates the first and second control signals, wherein the first and second control signals are sequentially enabled in response to pulses of the output pulse signal.

### BRIEF DESCRIPTION OF THE DRAWINGS

FIG. 1 is a block diagram illustrating an embodiment of a semiconductor device;

FIG. 2 is a block diagram illustrating an embodiment of a comparator of the semiconductor device shown in FIG. 1;

FIG. 3 is a logic table illustrating logic levels of digital signals generated according to a pulse width of an input pulse signal in an embodiment of a semiconductor device;

FIGS. 4, 5 and 6 are timing diagrams illustrating operations of an embodiment of a semiconductor device; and

FIG. 7 is a block diagram representation of a system including an embodiment of a semiconductor device.

### DETAILED DESCRIPTION OF THE EMBODIMENTS

Various embodiments will be described more fully hereinafter with reference to the accompanying drawings. However, the embodiments described herein are for illustrative purposes only and are not intended to limit the scope of the resent invention.

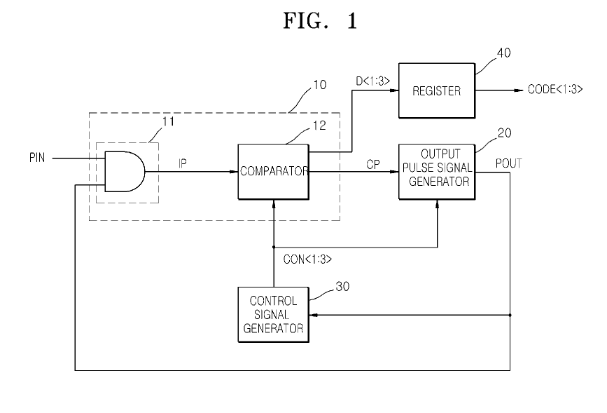

Referring to FIG. 1, an embodiment of a semiconductor device may include a pulse width comparator 10, an output pulse signal generator 20, a control signal generator 30 and a register 40.

The pulse width comparator 10 may include a first logic unit 11 and a comparator 12. The first logic unit 11 may generate an internal pulse signal IP including a pulse having substantially the same width as a pulse of an output pulse signal POUT during a period corresponding to a pulse width of an input pulse signal PIN. The comparator 12 may generate first, second and third digital signals D<1>, D<2>, D<3> and a comparison pulse signal CP based on the internal pulse signal IP in accordance with a delay time. The delay time may be based on first, second and third control signals CON<1>, CON<2>, CON<3>. The generation of the first, second and third digital signals D<1>, D<2>, D<3> and the comparison pulse signal CP based on the internal pulse signal IP will be described in further detail below.

The output pulse signal generator 20 may delay the comparison pulse signal CP by the delay time based on the first, second and third control signals CON<1>, CON<2>, CON<3> to generate the output pulse signal POUT.

An operation of the output pulse signal generator 20 generating the output pulse signal POUT will be described more fully hereinafter.

The output pulse signal generator 20 may delay the comparison pulse signal CP by a first delay time to generate the output pulse signal POUT when the first control signal CON<1> is enabled. The first control signal CON<1> may have a logic “high” level when enabled. The first delay time may be set to be greater than a pulse width of the input pulse signal PIN.

The output pulse signal generator 20 may delay the comparison pulse signal CP by a second delay time to generate the output pulse signal POUT when the second control signal CON<2> is enabled. The second delay time is approximately half of the first delay time. The second control signal CON<2> may have a logic “high” level when enabled.

The output pulse signal generator 20 may delay the comparison pulse signal CP by a third delay time to generate the output pulse signal POUT when the third control signal CON<3> is enabled. The third delay time is approximately half of the second delay time. The third control signal CON<3> may have a logic “high” level when enabled.

The control signal generator 30 may generate the first, second and third control signals CON<1>, CON<2>, CON<3>. The first, second and third control signals CON<1>, CON<2>, CON<3> are sequentially enabled in response to pulses of the output pulse signal POUT.

The generation of sequentially enabled first, second and third control signals CON<1>, CON<2>, <3> by the control signal generator 30 based on the output pulse signal POUT will be described more fully hereinafter.

The control signal generator 30 may generate the first control signal CON<1> having a logic “high” level, the second control signal CON<2> having a logic “low” level and the third control signal CON<3> having a logic “low” level in response to receiving a first pulse of the output pulse signal POUT as an input.

The control signal generator 30 may generate the second control signal CON<1> having a logic “low” level, the second control signal CON<2> having a logic “high” level and the third control signal CON<3> having a logic “low” level in response to receiving a second pulse of the output pulse signal POUT as an input.

The control signal generator 30 may generate the first control signal CON<1> having a logic “low” level, the second control signal CON<2> having a logic “low” level and the third control signal CON<3> having a logic “high” level in response to receiving a third pulse of the output pulse signal POUT as an input.

The register 40 may sequentially store the first, second and third digital signals D<1>, D<2>, D<3> and may output the stored first, second and third digital signals D<1>, D<2>, D<3> as first, second and third code signals CODE<1>, CODE<2>, CODE<3>. The register 40 may be realized using a plurality of flip-flops. The first, second and third code signals CODE<1>, CODE<2>, CODE<3> may be applied to a circuit such as a phase locked loop (PLL) circuit to transmit information on a pulse width of the input pulse signal PIN.

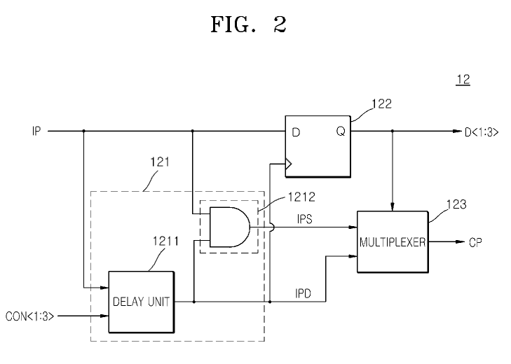

Referring to FIG. 2, the comparator 12 may include a pulse width controller 121, a flip-flop 122 and a multiplexer 123.

The pulse width controller 121 may include a delay unit 1211 and a second logic unit 1212. The delay unit 1211 may delay the internal pulse signal IP by a delay time based on the first, second and third control signals CON<1>, CON<2>, CON<3> to generate a delay pulse signal IPD. The second logic unit 1212 may generate a synthetic pulse signal IPS including a pulse having substantially the same width as a pulse of the delay pulse signal IPD during a period corresponding to a pulse width of the internal pulse signal IP. The pulse width controller 121 may delay the internal pulse signal IP by a delay time based on the first, second and third control signals CON<1>, CON<2>, CON<3> to generate the delay pulse signal IPD. The pulse width controller 121 may generate the synthetic pulse signal IPS including a pulse having substantially the same width as a pulse of the delay pulse signal IPD during a period corresponding to a pulse width of the internal pulse signal IP.

The generation of the delay pulse signal IPD by the delay unit 1211 where the delay pulse signal IPD is obtained by delaying the internal pulse signal IP by a delay time based on the first, second and third control signals CON<1>, CON<2>, CON<3> will be described more fully hereinafter.

The delay unit 1211 may delay the internal pulse signal IP by the second delay time to generate the delay pulse signal IPD when the first control signal CON<1> is enabled. The first control signal CON<1> may have a logic “high” level when enabled. The second delay time may be approximately half of the first delay time.

The delay unit 1211 may delay the internal pulse signal IP by the third delay time to generate the delay pulse signal IPD when the second control signal CON<2> is enabled. The second control signal CON<2> may have a logic “high” level when enabled. The third delay time may be approximately half of the second delay time.

The delay unit 1211 may delay the internal pulse signal IP by a fourth delay time to generate the delay pulse signal IPD when the third control signal CON<3> is enabled. The third control signal CON<3> may have a logic “high” level when enabled. The fourth delay time may be approximately half of the third delay time.

The flip-flop 122 may repeatedly and serially output the internal pulse signal IP as the first, second and third digital signals D<1>, D<2>, D<3> in synchronization with pulses of the delay pulse signal IPD. While FIG. 2 illustrates a flip-flop 122 including a single flip-flop, in alternative embodiments, the flip-flop 122 may include plurality of flip-flops to output the first, second and third digital signals D<1>, D<2>, D<3> from associated ones of the plurality of flip-flops.

The multiplexer 123 may output the synthetic pulse signal IPS as the comparison pulse signal CP when the first, second and third digital signals D<1>, D<2>, D<3> have a logic “high” level. The multiplexer 123 may output the delay pulse signal IPD as the comparison pulse signal CP when the first, second and third digital signals D<1>, D<2>, D<3> have a logic “low” level.

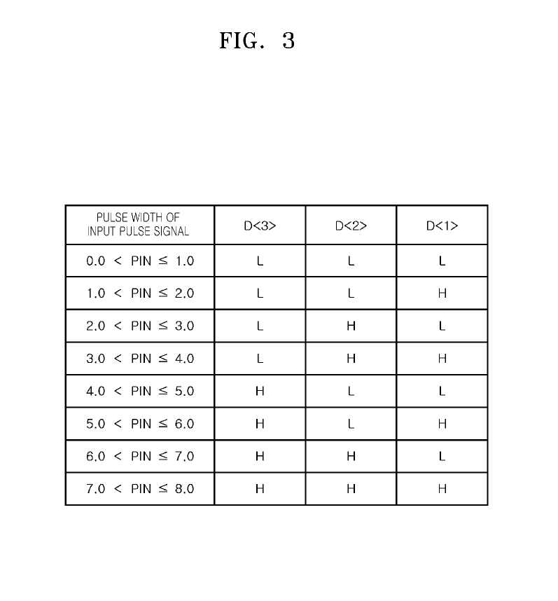

Logic levels of the first, second and third digital signals D<1>, D<2>, D<3> may be generated according to various pulse widths of the input pulse signal PIN will be described more fully hereinafter with reference to FIG. 3. A pulse width value of the input pulse signal PIN may have an arbitrary unit indicating time.

When a pulse width of the input pulse signal PIN is greater than 0.0 and less than or equal to 1.0, the first digital signal D<1> may be generated to have a logic “low(L)” level, the second digital signal D<2> may be generated to have a logic “low(L)” level, and the third digital signal D<3> may be generated to have a logic “low(L)” level.

When a pulse width of the input pulse signal PIN is greater than 1.0 and less than or equal to 2.0, the first digital signal D<1> may be generated to have a logic “high(H)” level, the second digital signal D<2> may be generated to have a logic “low(L)” level, and the third digital signal D<3> may be generated to have a logic “low(L)” level.

When a pulse width of the input pulse signal PIN is greater than 2.0 and less than or equal to 3.0, the first digital signal D<1> may be generated to have a logic “low(L)” level, the second digital signal D<2> may be generated to have a logic “high(H)” level, and the third digital signal D<3> may be generated to have a logic “low(L)” level.

When a pulse width of the input pulse signal PIN is greater than 3.0 and less than or equal to 4.0, the first digital signal D<1> may be generated to have a logic “high(H)” level, the second digital signal D<2> may be generated to have a logic “high(H)” level, and the third digital signal D<3> may be generated to have a logic “low(L)” level.

When a pulse width of the input pulse signal PIN is greater than 4.0 and less than or equal to 5.0, the first digital signal D<1> may be generated to have a logic “low(L)” level, the second digital signal D<2> may be generated to have a logic “low(L)” level, and the third digital signal D<3> may be generated to have a logic “high(H)” level.

When a pulse width of the input pulse signal PIN is greater than 5.0 and less than or equal to 6.0, the first digital signal D<1> may be generated to have a logic “high(H)” level, the second digital signal D<2> may be generated to have a logic “low(L)” level, and the third digital signal D<3> may be generated to have a logic “high(H)” level.

When a pulse width of the input pulse signal PIN is greater than 6.0 and less than or equal to 7.0, the first digital signal D<1> may be generated to have a logic “low(L)” level, the second digital signal D<2> may be generated to have a logic “high(H)” level, and the third digital signal D<3> may be generated to have a logic “high(H)” level.

When a pulse width of the input pulse signal PIN is greater than 7.0 and less than or equal to 8.0, the first digital signal D<1> may be generated to have a logic “high(H)” level, the second digital signal D<2> may be generated to have a logic “high(H)” level, and the third digital signal D<3> may be generated to have a logic “high(H)” level.

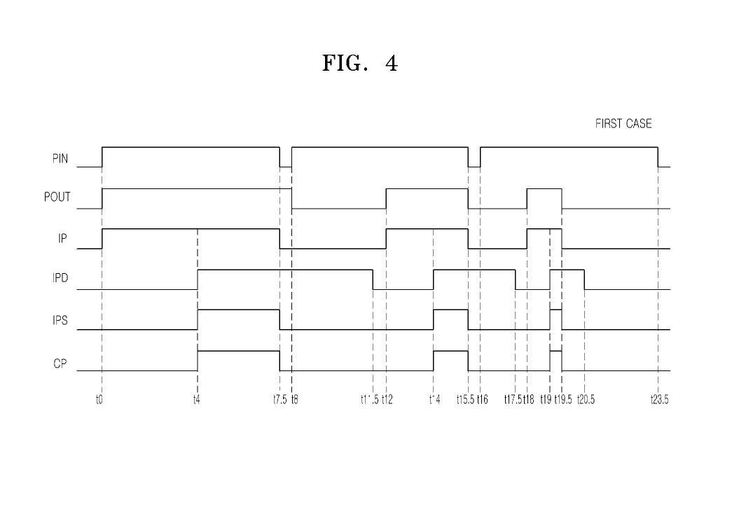

An operation of the semiconductor device having the aforementioned configuration will be described hereinafter with reference to FIGS. 4, 5 and 6. The description will be provided in conjunction with an example where the first delay time is based on a pulse width of 8.0 and the first, second and third digital signals D<1>, D<2>, D<3> are generated in accordance with a pulse width of the input pulse signal PIN. Tt may be assumed that the numeral indicating the pulse width is consistent with the numeral indicating a point in time in FIGS. 4, 5 and 6. It will be understood that a pulse width of 8 is equal to a time interval between a time “T0” and a time “T8”.

In a first case where a pulse width of the input pulse signal PIN is 7.5, the generation of the first, second and third digital signals D<1>, D<2>, D<3> will be described hereinafter with reference to FIG. 4.

The first logic unit 11 may receive the input pulse signal PIN having a pulse width of a logic “high” level during a time interval from a time “T0” till a time “T7.5” and the output pulse signal POUT having a pulse width of a logic “high” level during a time interval from a time “T0” till a time “T8” to generate the internal pulse signal IP having a pulse width of a logic “high” level during a time interval from a time “T0” till a time “T7.5”. The output pulse signal POUT may be input to the first logic unit 11 to have a pulse width of 8 during a time interval from a time “T0” till a time “T8”.

The control signal generator 30 may receive the output pulse signal POUT having a logic “high” level at a time “T0” to generate the first control signal CON<1> having a logic “high” level, the second control signal CON<2> having a logic “low” level, and the third control signal CON<3> having a logic “low” level.

The delay unit 1211 of the comparator 12 may delay the internal pulse signal IP by the second delay time in response to the first control signal CON<1> having a logic “high” level to generate the delay pulse signal IPD having a pulse width of a logic “high” level during a time interval from a time “T4” till a time “T11.5”.

The second logic unit 1212 may receive the internal pulse signal IP and the delay pulse signal IPD to generate the synthetic pulse signal IPS having a pulse width of a logic “high” level during a time interval from a time “T4” till a time “T7.5”.

The flip-flop 122 may output the internal pulse signal IP having a logic “high” level as the third digital signal D<3> at a time “T4” when a pulse of the delay pulse signal IPD is created. In such a case, the register 40 may store the third digital signal D<3> having a logic “high” level.

The multiplexer 123 may receive the third digital signal D<3> having a logic “high” level and responsively output the synthetic pulse signal IPS as the comparison pulse signal CP.

The output pulse signal generator 20 may delay the comparison pulse signal CP by the first delay time in response to the first control signal CON<1> having a logic “high” level to generate the output pulse signal POUT having a pulse width of a logic “high” level during a time interval from a time “T12” till a time “T15.5”.

The control signal generator 30 may receive the output pulse signal POUT having a logic “high” level at a time “T12” to generate the first control signal CON<1> having a logic “low” level, the second control signal CON<2> having a logic “high” level and the third control signal CON<3> having a logic “low” level.

The first logic unit 11 may receive the input pulse signal PIN having a pulse width of a logic “high” level during a time interval from a time “T8” till a time “T15.5” and the output pulse signal POUT having a pulse width of a logic “high” level during a time interval from a time “T12” till a time “T15.5” to generate the internal pulse signal IP having a pulse width of a logic “high” level during a time interval from a time “T12” till a time “T15.5”.

The delay unit 1211 of the comparator 12 may delay the internal pulse signal IP by the third delay time in response to the second control signal CON<2> having a logic “high” level to generate the delay pulse signal IPD having a pulse width of a logic “high” level during a time interval from a time “T14” till a time “T17.5”.

The second logic unit 1212 may receive the internal pulse signal IP and the delay pulse signal IPD to generate the synthetic pulse signal IPS having a pulse width of a logic “high” level during a time interval from a time “T14” till a time “T15.5”.

The flip-flop 122 may output the internal pulse signal IP having a logic “high” level as the second digital signal D<2> at a time “T14” when a pulse of the delay pulse signal IPD is created. In such a case, the register 40 may store the second digital signal D<2> having a logic “high” level.

The multiplexer 123 may receive the second digital signal D<2> having a logic “high” level to output the synthetic pulse signal IPS as the comparison pulse signal CP.

The output pulse signal generator 20 may delay the comparison pulse signal CP by the second delay time in response to the second control signal CON<2> having a logic “high” level to generate the output pulse signal POUT having a pulse width of a logic “high” level during a time interval from a time “T18” till a time “T19.5”.

The control signal generator 30 may receive the output pulse signal POUT having a logic “high” level at a time “T18” to generate the first control signal CON<1> having a logic “low” level, the second control signal CON<2> having a logic “low” level and the third control signal CON<3> having a logic “high” level.

The first logic unit 11 may receive the input pulse signal PIN having a pulse width of a logic “high” level during a time interval from a time “T16” till a time “T23.5” and the output pulse signal POUT having a pulse width of a logic “high” level during a time interval from a time “T18” till a time “T19.5” to generate the internal pulse signal IP having a pulse width of a logic “high” level during a time interval from a time “T18” till a time “T19.5”.

The delay unit 1211 of the comparator 12 may delay the internal pulse signal IP by the fourth delay time in response to the third control signal CON<3> having a logic “high” level to generate the delay pulse signal IPD having a pulse width of a logic “high” level during a time interval from a time “T19” till a time “T20.5”.

The second logic unit 1212 may receive the internal pulse signal IP and the delay pulse signal IPD to generate the synthetic pulse signal IPS having a pulse width of a logic “high” level during a time interval from a time “T19” till a time “T19.5”.

The flip-flop 122 may output the internal pulse signal IP having a logic “high” level as the first digital signal D<1> at a time “T19” when a pulse of the delay pulse signal IPD is created. In such a case, the register 40 may store the first digital signal D<1> having a logic “high” level.

In the case when the input pulse signal PIN having a pulse width of 7.5 is received at the semiconductor device, the first, second and third digital signals D<1>, D<2>, D<3> may be generated to have a logic level combination of ‘H,H,H’. The logic combination ‘H,H,H’ of the first, second and third digital signals D<1>, D<2>, D<3> indicates that the first digital signal D<1> has a logic “high(H)” level, the second digital signal D<2> has a logic “high(H)” level, and the third digital signal D<3> has a logic “high(H)” level.

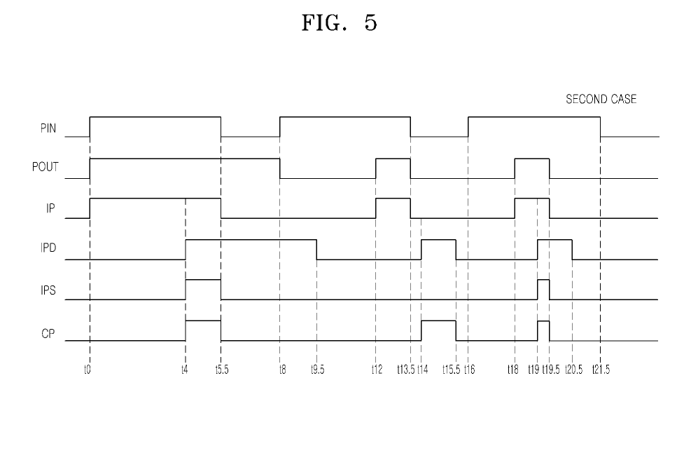

In a case where a pulse width of the input pulse signal PIN is 5.5, the generation of the first, second, and third digital signals D<1>, D<2>, D<3> will be described with reference to FIG. 5.

The first logic unit 11 may receive the input pulse signal PIN having a pulse width of a logic “high” level during a time interval from a time “T0” till a time “T5.5” and the output pulse signal POUT having a pulse width of a logic “high” level during a time interval from a time “T0” till a time “T8” to generate the internal pulse signal IP having a pulse width of a logic “high” level during a time interval from a time “T0” till a time “T5.5”. The output pulse signal POUT may be provided to the first logic unit 11 with a pulse width of 8 during a time interval from a time “T0” till a time “T8”.

The control signal generator 30 may receive the output pulse signal POUT having a logic “high” level at a time “T0” to generate the first control signal CON<1> having a logic “high” level, the second control signal CON<2> having a logic “low” level, and the third control signal CON<3> having a logic “low” level.

The delay unit 1211 of the comparator 12 may delay the internal pulse signal IP by the second delay time in response to the first control signal CON<1> having a logic “high” level to generate the delay pulse signal IPD having a pulse width of a logic “high” level during a time interval from a time “T4” till a time “T9.5”.

The second logic unit 1212 may receive the internal pulse signal IP and the delay pulse signal IPD to generate the synthetic pulse signal IPS having a pulse width of a logic “high” level during a time interval from a time “T4” till a time “T5.5”.

The flip-flop 122 may output the internal pulse signal IP having a logic “high” level as the third digital signal D<3> at a time “T4” when a pulse of the delay pulse signal IPD is created. In such a case, the register 40 may store the third digital signal D<3> having a logic “high” level.

The multiplexer 123 may receive the third digital signal D<3> having a logic “high” level to output the synthetic pulse signal IPS as the comparison pulse signal CP.

The output pulse signal generator 20 may delay the comparison pulse signal CP by the first delay time in response to the first control signal CON<1> having a logic “high” level to generate the output pulse signal POUT having a pulse width of a logic “high” level during a time interval from a time “T12” till a time “T13.5”.

The control signal generator 30 may receive the output pulse signal POUT having a logic “high” level at a time “T12” to generate the first control signal CON<1> having a logic “low” level, the second control signal CON<2> having a logic “high” level and the third control signal CON<3> having a logic “low” level.

The first logic unit 11 may receive the input pulse signal PIN having a pulse width of a logic “high” level during a time interval from a time “T8” till a time “T13.5” and the output pulse signal POUT having a pulse width of a logic “high” level during a time interval from a time “T12” till a time “T13.5” to generate the internal pulse signal IP having a pulse width of a logic “high” level during a time interval from a time “T12” till a time “T13.5”.

The delay unit 1211 of the comparator 12 may delay the internal pulse signal IP by the third delay time in response to the second control signal CON<2> having a logic “high” level to generate the delay pulse signal IPD having a pulse width of a logic “high” level during a time interval from a time “T14” till a time “T15.5”.

The second logic unit 1212 may receive the internal pulse signal IP and the delay pulse signal IPD and not generate the synthetic pulse signal IPS.

The flip-flop 122 may output the internal pulse signal IP having a logic “low” level as the second digital signal D<2> at a time “T14” when a pulse of the delay pulse signal IPD is created. In such a case, the register 40 may store the second digital signal D<2> having a logic “low” level.

The multiplexer 123 may receive the second digital signal D<2> having a logic “low” level to output the delay pulse signal IPD as the comparison pulse signal CP.

The output pulse signal generator 20 may delay the comparison pulse signal CP by the second delay time in response to the second control signal CON<2> having a logic “high” level to generate the output pulse signal POUT having a pulse width of a logic “high” level during a time interval from a time “T18” till a time “T19.5”.

The control signal generator 30 may receive the output pulse signal POUT having a logic “high” level at a time “T18” to generate the first control signal CON<1> having a logic “low” level, the second control signal CON<2> having a logic “low” level and the third control signal CON<3> having a logic “high” level.

The first logic unit 11 may receive the input pulse signal PIN having a pulse width of a logic “high” level during a time interval from a time “T16” till a time “T21.5” and the output pulse signal POUT having a pulse width of a logic “high” level during a time interval from a time “T18” till a time “T19.5” to generate the internal pulse signal IP having a pulse width of a logic “high” level during a time interval from a time “T18” till a time “T19.5”.

The delay unit 1211 of the comparator 12 may delay the internal pulse signal IP by the fourth delay time in response to the third control signal CON<3> having a logic “high” level to generate the delay pulse signal IPD having a pulse width of a logic “high” level during a time interval from a time “T19” till a time “T20.5”.

The second logic unit 1212 may receive the internal pulse signal IP and the delay pulse signal IPD to generate the synthetic pulse signal IPS having a pulse width of a logic “high” level during a time interval from a time “T19” till a time “T19.5”.

The flip-flop 122 may output the internal pulse signal IP having a logic “high” level as the first digital signal D<1> at a time “T19” when a pulse of the delay pulse signal IPD is created. In such a case, the register 40 may store the first digital signal D<1> having a logic “high” level.

In the case where the input pulse signal PIN has a pulse width of 5.5 is received at the semiconductor device, the first, second and third digital signals D<1>, D<2>, D<3> may be generated to have a logic level combination of ‘H,L,H’. The logic combination ‘H,L,H’ of the first, second and third digital signals D<1>, D<2>, D<3> indicates that the first digital signal D<1> has a logic “high(H)” level, the second digital signal D<2> has a logic “low(L)” level, and the third digital signal D<3> has a logic “high(H)” level.

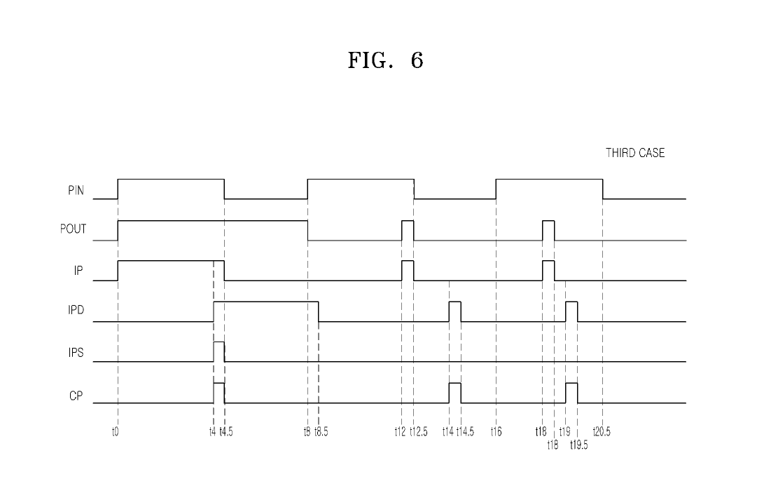

In a case where a pulse width of the input pulse signal PIN is 4.5, the generation of the first, second and third digital signals D<1>, D<2>, D<3> will be described with reference to FIG. 6.

The first logic unit 11 may receive the input pulse signal PIN having a pulse width of a logic “high” level during a time interval from a time “T0” till a time “T4.5” and the output pulse signal POUT having a pulse width of a logic “high” level during a time interval from a time “T0” till a time “T8” to generate the internal pulse signal IP having a pulse width of a logic “high” level during a time interval from a time “T0” till a time “T4.5”. The output pulse signal POUT may be input to the first logic unit 11 to have a pulse width of 8 during a time interval from a time “T0” till a time “T8”.

The control signal generator 30 may receive the output pulse signal POUT having a logic “high” level at a time “T0” to generate the first control signal CON<1> having a logic “high” level, the second control signal CON<2> having a logic “low” level, and the third control signal CON<3> having a logic “low” level.

The delay unit 1211 of the comparator 12 may delay the internal pulse signal IP by the second delay time in response to the first control signal CON<1> having a logic “high” level to generate the delay pulse signal IPD having a pulse width of a logic “high” level during a time interval from a time “T4” till a time “T8.5”.

The second logic unit 1212 may receive the internal pulse signal IP and the delay pulse signal IPD to generate the synthetic pulse signal IPS having a pulse width of a logic “high” level during a time interval from a time “T4” till a time “T4.5”.

The flip-flop 122 may output the internal pulse signal IP having a logic “high” level as the third digital signal D<3> at a time “T4” when a pulse of the delay pulse signal IPD is created. In such a case, the register 40 may store the third digital signal D<3> having a logic “high” level.

The multiplexer 123 may receive the third digital signal D<3> having a logic “high” level to output the synthetic pulse signal IPS as the comparison pulse signal CP.

The output pulse signal generator 20 may delay the comparison pulse signal CP by the first delay time in response to the first control signal CON<1> having a logic “high” level to generate the output pulse signal POUT having a pulse width of a logic “high” level during a time interval from a time “T12” till a time “T12.5”.

The control signal generator 30 may receive the output pulse signal POUT having a logic “high” level at a time “T12” to generate the first control signal CON<1> having a logic “low” level, the second control signal CON<2> having a logic “high” level and the third control signal CON<3> having a logic “low” level.

The first logic unit 11 may receive the input pulse signal PIN having a pulse width of a logic “high” level during a time interval from a time “T8” till a time “T12.5” and the output pulse signal POUT having a pulse width of a logic “high” level during a time interval from a time “T12” till a time “T12.5” to generate the internal pulse signal IP having a pulse width of a logic “high” level during a time interval from a time “T12” till a time “T12.5”.

The delay unit 1211 of the comparator 12 may delay the internal pulse signal IP by the third delay time in response to the second control signal CON<2> having a logic “high” level to generate the delay pulse signal IPD having a pulse width of a logic “high” level during a time interval from a time “T14” till a time “T14.5”.

The second logic unit 1212 may receive the internal pulse signal IP and the delay pulse signal IPD and not generate the synthetic pulse signal IPS

The flip-flop 122 may output the internal pulse signal IP having a logic “low” level as the second digital signal D<2> at a time “T14” when a pulse of the delay pulse signal IPD is created. In such a case, the register 40 may store the second digital signal D<2> having a logic “low” level.

The multiplexer 123 may receive the second digital signal D<2> having a logic “low” level to output the delay pulse signal IPD as the comparison pulse signal CP.

The output pulse signal generator 20 may delay the comparison pulse signal CP by the second delay time in response to the second control signal CON<2> having a logic “high” level to generate the output pulse signal POUT having a pulse width of a logic “high” level during a time interval from a time “T18” till a time “T18.5”.

The control signal generator 30 may receive the output pulse signal POUT having a logic “high” level at a time “T18” to generate the first control signal CON<1> having a logic “low” level, the second control signal CON<2> having a logic “low” level and the third control signal CON<3> having a logic “high” level.

The first logic unit 11 may receive the input pulse signal PIN having a pulse width of a logic “high” level during a time interval from a time “T16” till a time “T20.5” and the output pulse signal POUT having a pulse width of a logic “high” level during a time interval from a time “T18” till a time “T18.5” to generate the internal pulse signal IP having a pulse width of a logic “high” level during a time interval from a time “T18” till a time “T18.5”.

The delay unit 1211 of the comparator 12 may delay the internal pulse signal IP by the fourth delay time in response to the third control signal CON<3> having a logic “high” level to generate the delay pulse signal IPD having a pulse width of a logic “high” level during a time interval from a time “T19” till a time “T19.5”.

The second logic unit 1212 may receive the internal pulse signal IP and the delay pulse signal IPD and not generate the synthetic pulse signal IPS.

The flip-flop 122 may output the internal pulse signal IP having a logic “low” level as the first digital signal D<1> at a time “T19” when a pulse of the delay pulse signal IPD is created. In such a case, the register 40 may store the first digital signal D<1> having a logic “low” level.

In the case where the input pulse signal PIN having a pulse width of 4.5 is received at inputted the semiconductor device, the first, second and third digital signals D<1>, D<2>, D<3> may be generated to have a logic level combination of ‘H,L,L’. The logic combination ‘H,L,L’ of the first, second and third digital signals D<1>, D<2>, D<3> indicates that the first digital signal D<1> has a logic “low(L)” level, the second digital signal D<2> has a logic “low(L)” level, and the third digital signal D<3> has a logic “high(H)” level.

An embodiment of the semiconductor device having the aforementioned configuration may covert a pulse width of a pulse signal that is received as an input into a digital signal using a successive approximate register.

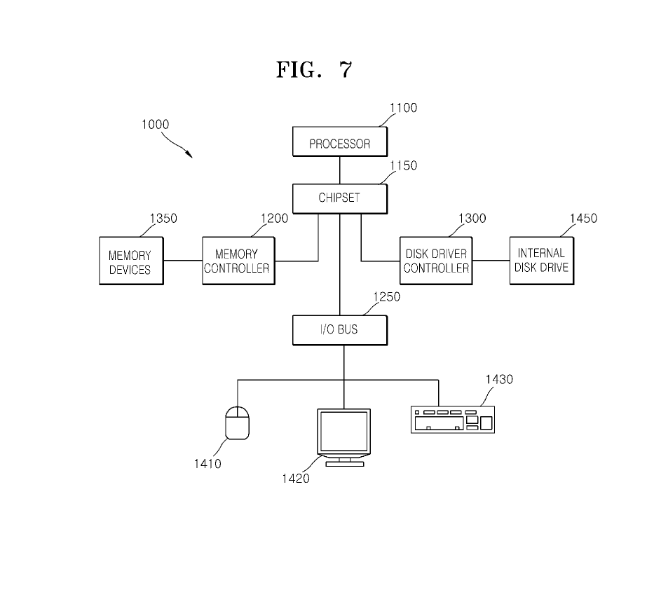

Referring to FIG. 7, a block diagram representation of a system 1000 including an embodiment of a semiconductor device 1350 is shown. In an embodiment, the semiconductor device 1350 is the semiconductor device of FIG. 1. In an embodiment, the semiconductor device 1350 is a semiconductor memory device. The system 1000 includes one or more semiconductor memory devices 1350 and a memory controller 1200

Examples of the semiconductor memory device 1350 include, but are not limited to, dynamic random access memory, static random access memory, synchronous dynamic random access memory (SDRAM), synchronous graphics random access memory (SGRAM), double data rate dynamic ram (DDR), and double data rate SDRAM.

The memory controller 1200 is used in the design of memory devices, processors, and computer systems. The system 1000 may include one or more processors or central processing units (“CPUs”) 1100. The CPU 1100 may be used individually or in combination with other CPUs. While the CPU 1100 will be referred to primarily in the singular, it will be understood by those skilled in the art that a system with any number of physical or logical CPUs may be implemented

A chipset 1150 may be electrically coupled to the CPU 1100. The chipset 1150 is a communication pathway for signals between the CPU 1100 and other components of the system 1000, which may include the memory controller 1200, an input/output (“I/O”) bus 1250, and a disk drive controller 1300. Depending on the configuration of the system 1000, any one of a number of different signals may be transmitted through the chipset 1150, and those skilled in the art will appreciate that the routing of the signals throughout the system 1000 can be readily adjusted without changing the underlying nature of the system.

As stated above, the memory controller 1200 may be electrically coupled to the chipset 1150. The memory controller 1200 can receive a request provided from the CPU 1100, through the chipset 1150. In alternate embodiments, the memory controller 1200 may be integrated into the chipset 1150. The memory controller 1200 may be electrically coupled to one or more memory devices 1350. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may be electrically coupled to the I/O bus 1250. The I/O bus 1250 may serve as a communication pathway for signals from the chipset 1150 to I/O devices 1410, 1420 and 1430. The I/O devices 1410, 1420 and 1430 may include a mouse 1410, a video display 1420, or a keyboard 1430. The I/O bus 1250 may employ any one of a number of communications protocols to communicate with the I/O devices 1410, 1420, and 1430. Further, the I/O bus 1250 may be integrated into the chipset 1150.

The disk drive controller 1450 may also be electrically coupled to the chipset 1150. The disk drive controller 1450 may serve as the communication pathway between the chipset 1150 and one or more internal disk drives 1450. The internal disk drive 1450 may facilitate disconnection of the external data storage devices by storing both instructions and data. The disk drive controller 1300 and the internal disk drives 1450 may communicate with each other or with the chipset 1150 using virtually any type of communication protocol, including all of those mentioned above with regard to the I/O bus 1250.

The system 1000 described above in relation to FIG. 7 is merely one example of a system employing a semiconductor memory device 1350. In alternate embodiments, such as cellular phones or digital cameras, the components may differ from the embodiment shown in FIG. 5.

While certain embodiments have been described above, it will be understood to those skilled in the art that the embodiments described are by way of example only. Accordingly, the semiconductor device described herein should not be limited based on the described embodiments. Rather, the semiconductor device described herein should only be limited in light of the claims that follow when taken in conjunction with the above description and accompanying drawings.

What is claimed is:

1. A semiconductor device comprising:
a pulse width comparator suitable for generating an internal pulse signal including a pulse having substantially the same pulse width as a pulse of an output pulse signal, wherein the pulse width of the output pulse signal is based on first and second control signals during a period corresponding to a pulse width of an input pulse signal and generating first and second digital signals and a comparison pulse signal based on the internal pulse signal in accordance with a delay time based on the first and second control signals;
an output pulse signal generator suitable for delaying the comparison pulse signal by the delay time based on the first and second control signals to generate the output pulse signal; and
a control signal generator suitable for generating the first and second control signals, wherein the first and second control signals are sequentially enabled in response to pulses of the output pulse signal.

2. The semiconductor device of claim 1, wherein the first and second digital signals include information associated with the pulse width of the input pulse signal.

3. The semiconductor device of claim 1, wherein the output pulse signal is generated by delaying the comparison pulse signal by a first delay time, wherein the first delay time is relatively greater than the pulse width of the input pulse signal, when the first control signal is enabled.

4. The semiconductor device of claim 3, wherein the output pulse signal is generated by delaying the comparison pulse signal by a second delay time when the second control signal is enabled, wherein the second delay time is approximately half of the first delay time.

5. The semiconductor device of claim 4, wherein the pulse width comparator comprises:
a first logic unit suitable for generating the internal pulse signal including the pulse having substantially the same width as the pulse of the output pulse signal during a period corresponding to the pulse width of the input pulse signal; and
a comparator suitable for delaying the internal pulse signal by a delay time based on a logic level combination of the first and second control signals to generate a delay pulse signal, outputting the internal pulse signal as the first and second digital signals in synchronization with pulses of the delay pulse signal, and generating the comparison pulse signal in response to the first and second digital signals.

6. The semiconductor device of claim 5, wherein the comparator comprises:
a pulse width controller suitable for delaying the internal pulse signal by the delay time based on the first and second control signals to generate the delay pulse signal and buffering the delay pulse signal in response to the internal pulse signal to generate a synthetic pulse signal;
a flip-flop suitable for outputting the internal pulse signal as the first and second digital signals in response to the creation of pulses of the delay pulse signal; and
a multiplexer suitable for outputting one of the synthetic pulse signal and the delay pulse signal as the comparison pulse signal in response to the first and second digital signals.

7. The semiconductor device of claim 6, wherein the pulse width controller comprises:
a second logic unit suitable for generating the synthetic pulse signal including a pulse having substantially the same width as the pulse of the delay pulse signal in a period corresponding to the pulse width of the internal pulse signal; and
a delay unit suitable for delaying the internal pulse signal by the based on a logic level combination of the first and second control signals to generate the delay pulse signal.

8. The semiconductor device of claim 7, wherein the delay pulse signal is generated by delaying the internal pulse signal by the second delay time when the first control signal is enabled.

9. The semiconductor device of claim 8, wherein the delay pulse signal is generated by delaying the internal pulse signal by a third delay time when the second control signal is enabled, wherein the third delay time is approximately half of the second delay time.

10. The semiconductor device of claim 1, further comprising a register suitable for sequentially storing the first and second digital signals and outputting the stored first and second digital signals as first and second code signals.

11. A semiconductor device comprising:
a first logic unit suitable for generating an internal pulse signal including a pulse having substantially a same width as a pulse of an output pulse signal during a period corresponding to a pulse width of an input pulse signal;
a comparator suitable for delaying the internal pulse signal by a delay time based on a logic level combination of first and second control signals to generate a delay pulse signal, outputting the internal pulse signal as first and second digital signals in synchronization with pulses of the delay pulse signal, and generating a comparison pulse signal in response to the first and second digital signals; and
an output pulse signal generator suitable for delaying the comparison pulse signal by the delay time based on the first and second control signals to generate the output pulse signal.

12. The semiconductor device of claim 11, wherein the first and second digital signals include information associated with the pulse width of the input pulse signal.

13. The semiconductor device of claim 11, wherein the first and second control signals are sequentially enabled in synchronization with pulses of the output pulse signal.

14. The semiconductor device of claim 11, wherein the output pulse signal is generated by delaying the comparison pulse signal by a first delay time when the first control signal is enabled, wherein the first delay time is greater than the pulse width of the input pulse signal.

15. The semiconductor device of claim 14, wherein the output pulse signal is generated by delaying the comparison pulse signal by a second delay time when the second control signal is enabled, wherein the second delay time is approximately half of the first delay time.

16. The semiconductor device of claim 15, wherein the comparator comprises:
a pulse width controller suitable for delaying the internal pulse signal by a delay time based on the first and second control signals to generate the delay pulse signal and buffering the delay pulse signal in response to the internal pulse signal to generate a synthetic pulse signal;
a flip-flop suitable for outputting the internal pulse signal as the first and second digital signals in response to the creation of pulses of the delay pulse signal; and
a multiplexer suitable for outputting one of the synthetic pulse signal and the delay pulse signal as the comparison pulse signal in response to the first and second digital signals.

17. The semiconductor device of claim 16, wherein the pulse width controller comprises:
a second logic unit suitable for generating the synthetic pulse signal including a pulse having substantially the same width as the pulse of the delay pulse signal in a period corresponding to the pulse width of the internal pulse signal; and
a delay unit suitable for delaying the internal pulse signal by the based on a logic level combination of the first and second control signals to generate the delay pulse signal.

18. The semiconductor device of claim 17, wherein the delay pulse signal is generated by delaying the internal pulse signal by the second delay time when the first control signal is enabled.

19. The semiconductor device of claim 18, wherein the delay pulse signal is generated by delaying the internal pulse signal by a third delay time when the second control signal is enabled, wherein the third delay time is approximately half of the second delay time.

20. A system comprising:
a memory controller; and
a semiconductor memory device comprising:
a pulse width comparator suitable for generating an internal pulse signal including a pulse having substantially the same pulse width as a pulse of an output pulse signal, wherein the pulse width of the output pulse signal is based on first and second control signals during a period corresponding to a pulse width of an input pulse signal and generating first and second digital signals and a comparison pulse signal based on the internal pulse signal in accordance with a delay time based on the first and second control signals;
an output pulse signal generator suitable for delaying the comparison pulse signal by the delay time based on the first and second control signals to generate the output pulse signal; and
a control signal generator suitable for generating the first and second control signals, wherein the first and second control signals are sequentially enabled in response to pulses of the output pulse signal.
